(19) United States
(12) Patent Application Publication
(10) Pub. No.: US 2002/0007676 A1
(43) Pub. Date: Jan. 24, 2002

(54) Package for electronic sports device and method of attaching same to objects

(76) Inventors: Michael A. Ward, Pasadena, MD (US); David L. Overman, Punta Gorda, FL (US); Albert E. Dilz JR., Cincinnati, OH (US); David L. Hunt, Cincinnati, OH (US); David K. Memke, Cincinnati, OH (US); David L. Slayton, Cincinnati, OH (US)

Correspondence Address: EPSTEIN, EDELL, SHAPIRO, FINNAN & LYTLE, LLC, Suite 400, 1901 Research Blvd., Rockville, MD, 20850-3164, US

(21) Appl. No.: 09/940,482

(22) Filed: Aug. 29, 2001

Related U.S. Application Data
(62) Division of application No. 09/471,905, filed on Dec. 23, 1999.
(62) Division of application No. 09/233,556, filed on Jan. 20, 1999, now Pat. No. 6,079,269.
Application No. 09/233,556 is a continuation of application No. 08/796,665, filed on Feb. 5, 1997, now Pat. No. 5,864,061.
(60) Provisional application No. 60/113,378, filed on Dec. 23, 1998.

(51) Int. Cl. G01R 19/04; G01P 1/02

(52) U.S. Cl. 73/493; 324/104; 473/503

(57) ABSTRACT

A package for a sporting device having a display and electrical components mounted on a pair of circuit boards includes a housing defining a chamber receiving the boards and the display, front and back covers on opposite sides of the housing, and a stiffener disposed between the boards. The packaging allows the sporting device to be attached to sports equipment such as ball catching gloves as well as parts of the body and clothing. For high impact loading, an optional shock-absorbing pad with spaced ribs can be mounted on a back face of the back cover.

### CROSS-REFERENCE TO RELATED APPLICATIONS

This application claims priority from Provisional Patent Application Ser. No. 60/113,378, filed on Dec. 23, 1998. This application is also a continuation-in-part of U.S. patent application Ser. No. 09/233,556, entitled “Miniature Sports Radar Speed Measuring Device”, filed on Jan. 20, 1999, which is a continuation of U.S. patent application Ser. No. 08/796,665, entitled “Miniature Sports Radar Speed Measuring Device”, filed on Feb. 5, 1997, now U.S. Pat. No. 5,864,061. The disclosures of the above-mentioned patent applications and patent are incorporated herein by reference in their entireties.

### BACKGROUND OF THE INVENTION

1. Field of the Invention

The present invention relates generally to a package or packaging for an electronic sports device and, more particularly, to packaging for a miniature sports radar device attached to portions of the body, clothing or sporting equipment to measure the velocity of a sports object such as a ball.

2. Discussion of the Related Art

It is desirable in many sporting activities to determine a parameter of motion of an object to assist in training a participant. For example, Doppler radar systems have been utilized in sports applications to measure the velocities of sports objects such as baseballs to provide feedback to players on their performance. In U.S. Pat. No. 5,864,061 (Dilz), for example, a miniature sports radar device is disclosed having electronic circuitry for measuring and displaying the velocity of a baseball thrown into a glove. The electronic circuitry of the miniature sports radar device is mounted on a pair of circuit boards packaged within a housing.

In the case of a miniature sports radar device, it is desirable to mount the device in approximately a direct line with, or at only a slight angle to, the flight of the ball or other object whose speed is being measured. The device is also preferably located such that the object passes within one or a few feet of the device somewhat in the path of the object, such as the endpoint or point of catch. To this end, the Dilz patent suggests mounting the device on the forearm of the catcher or on the glove. However, when a sporting device with electronic circuitry is positioned in the path of movement of a sports object such as a ball, the device can be subjected to impact forces that can damage the electronic circuitry thereby rendering the device inoperative.

Accordingly, there is a need to package sporting devices with electronic circuitry such that the devices can be mounted near moving objects for optimal performance without the risk of damaging sensitive components of the device.

### SUMMARY OF THE INVENTION

Accordingly, it is an object of the present invention to provide a package for an electronic sports device that allows the device to be attached to objects such as sporting equipment in an optimal position without the risk of sustaining damage due to impact loading.

The present invention is generally characterized in a package for a miniature sports radar device having a display and electrical components mounted on a pair of circuit boards and includes a housing defining a chamber receiving the boards and the display, front and back covers on opposite sides of the housing, and a stiffener disposed between the boards. The stiffener is preferably an open framework that couples the boards in a manner that increases the effective section of the boards in the direction of bending without significantly increasing the weight of the device. The packaging preferably includes eyelets that allow the sporting device to be attached to sports equipment such as ball catching gloves as well as parts of the body and clothing using a cord. For high impact loading, an optional shock-absorbing pad with spaced ribs can be mounted on a back face of the back cover.

Another aspect of the present invention is generally characterized in a method of attaching a radar velocity sensor to a ball catching glove with glove lacing including the steps of threading a cord through a plurality of eyelets extending from a package containing the radar velocity sensor, and attaching portions of the cord extending through the eyelets to the glove lacing.

Some of the advantages of the present invention are that the packaging allows the sporting device to be subject to impact loading without damage to sensitive components of the sporting device, that the packaging allows the sporting device to be attached to various types of sporting equipment and clothing to achieve optimum performance, that assembly of the sporting device can be accomplished quickly and easily, and that the size and weight of the sporting device can be minimized.

Other objects and advantages of the present invention will become apparent from the following description of the preferred embodiments taken with the accompanying drawings, wherein like parts in each of the several figures are identified by the same reference numerals.

### BRIEF DESCRIPTION OF THE DRAWINGS

FIG. 1 is a front view of a sporting device in the form of a radar velocity sensor packaged in accordance with the present invention.

FIG. 2 is an exploded front perspective view of the sporting device shown in FIG. 1.

FIG. 3 is a plan view of the front of a package housing for a sporting device according to the present invention.

FIG. 4 is a sectional view of the package housing taken through line 4-4 in FIG. 3.

FIG. 5 is a plan view of the rear of the package housing shown in FIG. 3.

FIG. 6 is a plan view of the front of a front cover for use with the packaging according to the present invention.

FIG. 7 is a sectional view of the front cover taken through line 7-7 in FIG. 6.

FIG. 8 is a plan view of the rear of the front cover shown in FIG. 6.

FIG. 9 is a plan view of the front of a display lens for use in sports device packaging according to the present invention.

FIG. 10 is a sectional view of the display lens taken through line 10-10 in FIG. 9.

FIG. 11 is a side view of the display lens shown in FIG. 9.

FIG. 12 is a plan view of the front of a button for use with the packaging according the present invention.

FIG. 13 is a sectional view of the button taken through line 13-13 in FIG. 12.

FIG. 14 is a plan view of the front of a stiffener for use with the packaging according to the present invention.

FIG. 15 is a sectional view of the stiffener taken through line 15-15 in FIG. 14.

FIG. 16 is a plan view of the rear of the stiffener shown in FIG. 13.

FIG. 17 is a plan view of the rear of a pad for attachment to the packaging according to the present invention.

FIG. 18 is a sectional view of the pad taken through line 18-18 in FIG. 17.

FIG. 19 is a plan view of the front of the pad shown in FIG. 17.

FIGS. 20A-20J are perspective views illustrating attachment of a sports device packaged in accordance with the present invention behind the fingers of a ball-catching glove.

FIG. 21 is a perspective view illustrating a modified method of attaching a sports device packaged in accordance with the present invention to a ball catching glove that does not have fingers.

FIG. 22 is a perspective view illustrating another modified method of attaching a sports device packaged in accordance with the present invention to a ball catching glove without fingers.

FIG. 23 is a perspective view of yet another method of attaching a sports device packaged in accordance with the present invention to a ball catching glove.

FIG. 24 is a perspective view of a sports device packaged in accordance with the present invention mounted on the web of a ball catching glove.

### DESCRIPTION OF THE PREFERRED EMBODIMENTS

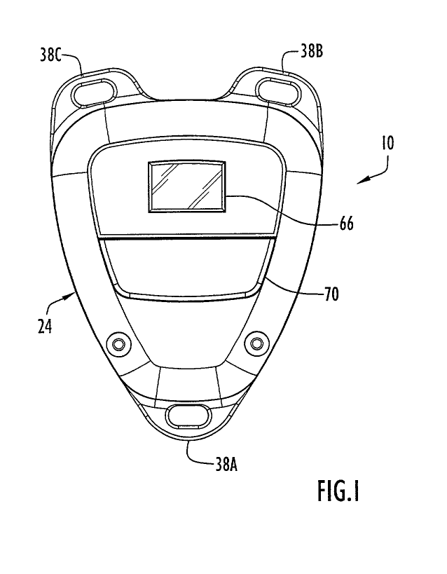

An electronic sports device 10 packaged in accordance with the present invention is shown in FIG. 1 as a miniature radar device of the type which can be attached to a baseball glove to measure the speed of a ball approaching the glove. The principles of operation of such a radar device are described in U.S. Pat. No. 5,864,061 and in U.S. patent application Ser. No. 09/233,556, filed on Jan. 20, 1999, and in U.S. Provisional Patent Application Ser. No. 60/113,434, filed on Dec. 23, 1998, the disclosures of which are incorporated herein by reference in their entireties. While a miniature radar device is shown, it will be appreciated that other types of electrical devices can be packaged for sporting use in accordance with the present invention. It will also be appreciated that a sporting device packaged in accordance with the present invention can be attached to other types of sporting equipment as well as other objects such as parts of the body and clothing.

Referring to FIG. 2, it can be seen that sporting device 10 generally includes a display 12, a pair of circuit boards 14 and 16 mounting electronic components, a button assembly 18, and a battery 20; the display, boards, button and battery making up the operational components of the device. The sporting device packaging generally includes an inner shell or housing 22 defining compartments for the operational components of the device, front and rear covers 24 and 26 on opposite sides of the housing, a stiffener 28 disposed between the boards, and an optional shock-absorbing pad 30 on the back face of the rear cover.

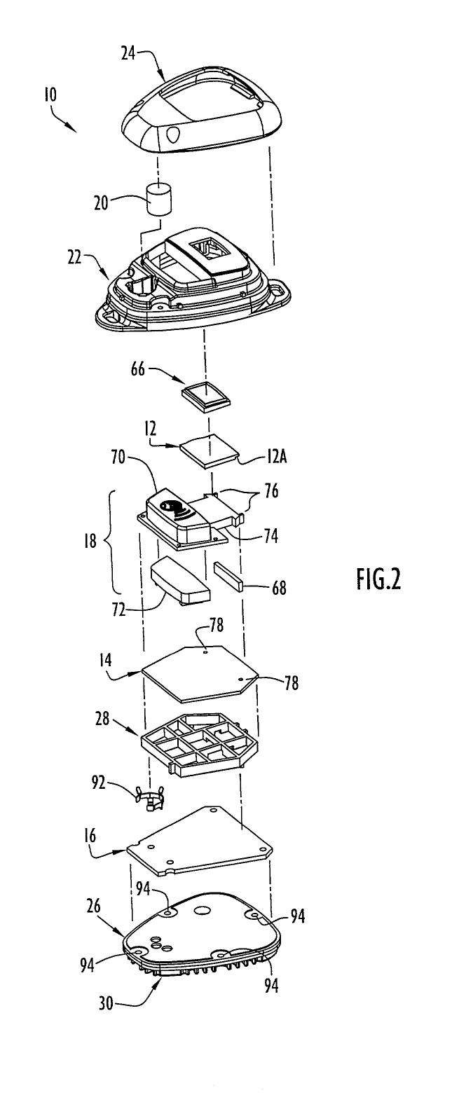

Referring to FIGS. 3-5, housing 22 includes a front face 32 of generally triangular configuration, a sidewall 34 extending rearwardly from the front face to define a rear compartment 36 for the operational components of the device, and three eyelets 38A, 38B and 38C extending outwardly from the rear edge of the sidewall at corners of the housing. As best seen in FIG. 4, the front face 32 of housing 22 is made up of stepped surfaces, a first surface 32A connecting with the sidewall, a second surface 32B projecting outward from the first and defining a forward-facing cylindrical compartment 40 for the battery at a first corner and a generally trapezoidal opening 42 across the center of the housing for the button, and a third surface 32C projecting outward from the second surface and defining a rectangular window 44 for the display between second and third corners of the housing. As best seen in FIG. 3, the periphery of the second surface is notched at a plurality of spaced locations to provide clearance for pilot holes 46 formed in the first surface on opposite sides of the battery compartment. So that only two screws are needed to attach the front cover to the housing, ribs 48 are formed along the periphery of the second surface at spaced locations to engage surfaces inside the front cover to prevent the cover from pivoting when screwed into the housing via the pilot holes.

Referring to FIGS. 4 and 5, it can be seen that the compartment 36 formed on the back side of housing 22 is made up of a first recess terminating at a first shoulder 36A for receiving the rear cover, a second recess extending forwardly from the first shoulder to a second shoulder 36B for receiving the second circuit board 16, a third recess extending forwardly from the second shoulder to a third shoulder 36C for receiving the first circuit board 14 and stiffener 28, and a fourth recess extending from the third shoulder to a fourth shoulder 36D for receiving the display 12. Pilot holes 50 are formed at a plurality of spaced locations around the first shoulder to receive screws attaching the rear cover 26 to the housing 22. A plurality of horizontal ribs 52 are disposed on opposite lateral sides of window 44 in the fourth recess and a pair of pins 54 extend rearwardly from the uppermost pair of ribs into the third recess to ensure alignment of the operational components by engaging features of the first circuit board as will be described in greater detail below. As best seen in FIG. 5, a key in the form of a vertical rib 56 also extends rearwardly from the third shoulder on one side of the battery compartment 40 to prevent the stiffener from being inserted backwards as will be described in greater detail below.

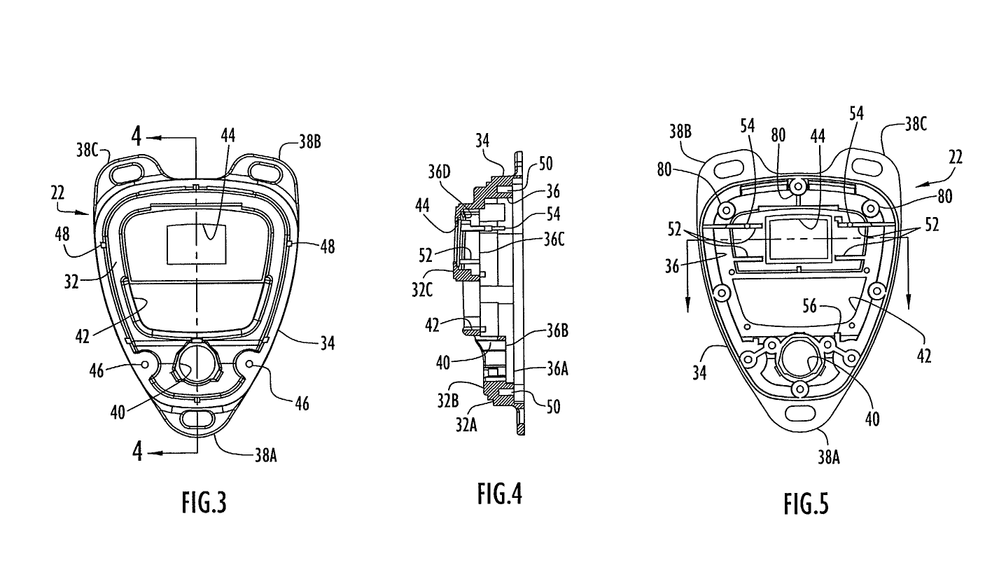

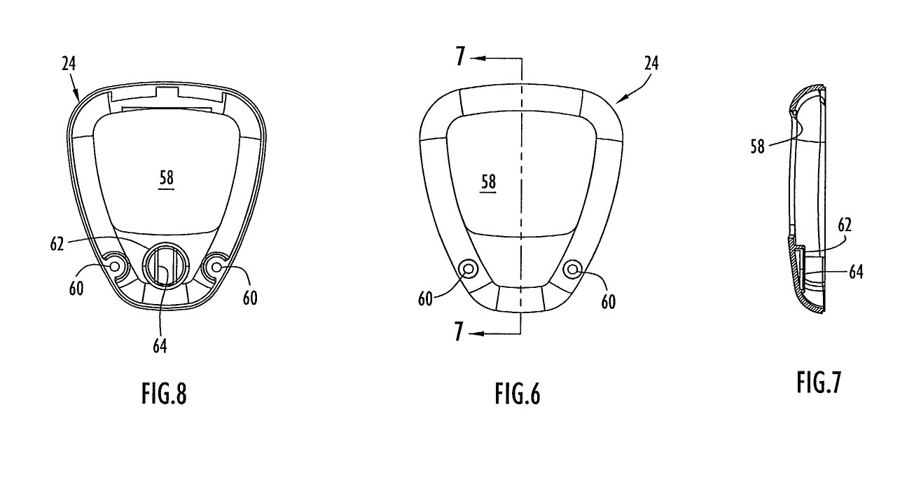

Referring again to FIG. 2, it can be seen that front cover 24 fits over the front surface of housing 22 to help seal the housing and to retain battery 20 in the battery compartment formed on the front of the housing. As best seen in FIGS. 6-8, front cover 24 is generally triangular in shape with rounded corners that fit telescopically over corresponding corners of the housing to rest on the first front surface 32A. A large trapezoidal cut-out 58 is formed through the front cover to allow the button assembly and display to protrude from the front cover. Recessed holes 60 are formed adjacent the cut-out 58 to receive screws attaching the front cover to the housing. A battery compartment cover 62 with terminal contact 64 is disposed on an interior of the front cover between holes 60 and is forced into electrical contact with a terminal of the battery when the cover is installed.

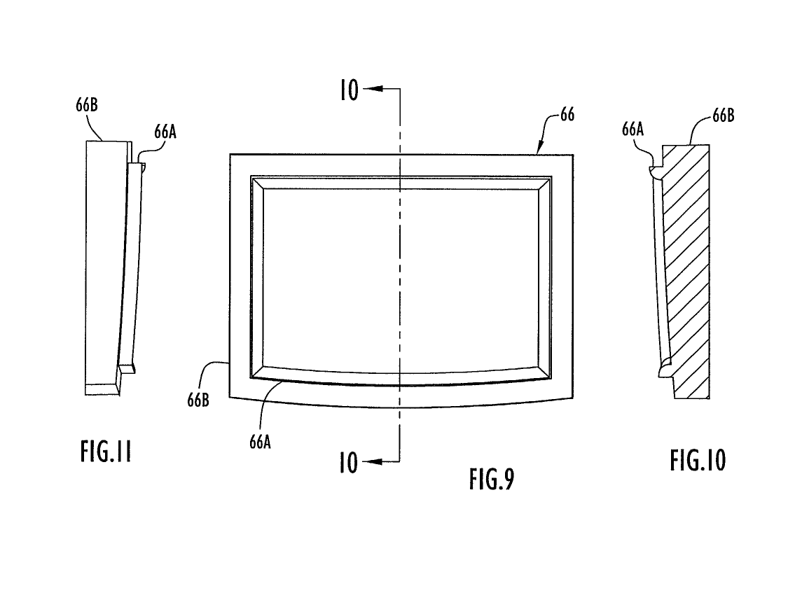

Referring again to FIG. 2, it can be seen that a rectangular lens 66 is disposed between the display 12 and the window 44 formed in housing 22 to protect the display while permitting the display to be viewed from outside the device. As best seen in FIGS. 9-11, lens 66 includes a front portion 66A that fits within the window framed by the fourth shoulder at the forward end of the fourth recess in the back compartment of the housing, and a rear portion 66B in the form of a lip that extends laterally outward from the front portion to abut the fourth shoulder when the lens is inserted into the window. The front portion of the lens fits snugly within the window to prevent lateral movement of the lens relative to the housing, with the lip being sandwiched between the display and the fourth shoulder to prevent the lens from passing completely through the window. The lens can be formed of any transparent material, but is preferably formed of polycarbonate plastic for impact resistance.

Referring again to FIG. 2, it can be seen that the display 12 fits within the fourth recess against the lens 66. The lens 66 and display 12 are laterally positioned between laterally spaced ribs 52 (FIG. 5) in the fourth recess such that the readout is aligned with the window 44 to facilitate easy viewing. The display is shown as a conventional liquid crystal display (LCD) of rectangular configuration; however, other types of displays can be used including back-lit and light-emitting diode (LED) displays and displays of other geometric configuration. In a preferred embodiment, an LCD with one millimeter segments and an overall size of about 19 millimeters by about 23 millimeters is used. One such display, illustrated in FIG. 2, includes a ledge 12A along a top edge thereof for receiving an elongate connector 68 formed of an elastomeric material to cushion the display. The connector 68 includes contacts which establish electrical connections between the display and the first circuit board which will typically have electronic components for driving the display. Some examples of the types of contacts that can be used include pins, pads and sockets.

Button assembly 18 is mounted on the forward facing side of the first circuit board 14 and, referring to FIG. 2, the button assembly includes a hollow, convex portion or button 70 protruding forwardly through the opening in the housing to serve as a button, a rigid insert 72 disposed telescopically within the convex portion to engage a switch on the first circuit board, and a pad 74 disposed between the upper portion of the first circuit board and the display as a shock absorbing element. As best seen in FIGS. 12 and 13, button 70 and pad 74 are connected by a flange 75 extending laterally outward from the base of the button to mount the first circuit board. Pad 74 is an elongate rectangular structure with sidewalls defining an air cavity of generally rectangular configuration between the display and the board. The connector 68 is positioned against an upper sidewall of pad 74 between a pair of ears 76 projecting from opposite ends of the upper sidewall to facilitate alignment during the assembly process. The convex portion and the insert are both generally trapezoidal in shape. The insert can be solid or hollow; however, if hollow, the insert preferably includes ribs which extend across the hollow interior of the insert to forcefully engage a dome switch on the circuit board when the button is depressed thereby activating a circuit such as the radar velocity sensor circuit described in U.S. Pat. No. 5,864,061 or U.S. Provisional Patent Application Ser. No. 60/113,434, filed on Dec. 23, 1998. The convex button and the pad can be made of any type of elastomeric material but are preferably made of Santoprene. The insert can be made of any relatively rigid material but is preferably formed of nylon. Preferably, the button and pad are formed as an integral one-piece unit as shown.

Referring again to FIG. 2, it can be seen that the first circuit board 14 is of generally hexagonal configuration with a pair of alignment holes 78 for receiving pins 54 extending rearwardly from ribs 52 in the back compartment of the housing 22 to ensure that the board is aligned to make electrical contact with the connector. Edges of the board are positioned between posts or bosses 80 extending rearwardly from the third recess on the back side of the housing to assist in aligning the holes in the board with the pins. As mentioned above, the first circuit board is preferably used to define an electrical circuit for driving the display.

The second circuit board 16 is disposed rearwardly of the first circuit board 14 and, in a preferred embodiment, the second board is used to define an RF circuit for measuring the velocity of a ball thrown into a glove. The principles of operation of such a circuit are described in U.S. Pat. No. 5,864,061 and in U.S. Provisional Patent Application Ser. No. 60/113,434, filed on Dec. 23, 1998, the disclosures of which are incorporated herein by reference. The second circuit board is shown as being generally trapezoidal in shape with upper corners clipped to fit within the generally triangular rear cover 26; however, rounded corners could also be used. The lower end of the second circuit board extends beyond the lower end of the first circuit board and includes a metallic dome switch (not shown) located in juxtaposed relation to the button insert so that, when the button is depressed, the rigid button insert will compress the dome switch to activate the circuit or otherwise initiate a function of the device. The use of a rigid insert is particularly beneficial when a metallic dome switch is used; however, the button can be formed without an insert, for example by forming ribs within the hollow region of the button to stiffen the structure. While a dome switch is described, it will be appreciated that other types of switches can be used including, but not limited to, switches wherein the button or button insert carries a conductor for bridging a gap between contacts on the circuit board.

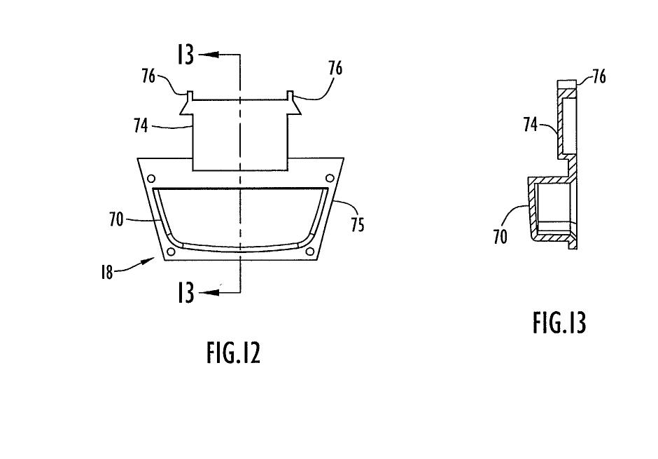

Referring still to FIG. 2, it can be seen that stiffener 28 is disposed between the first and second circuit boards 14 and 16. Stiffener 28 is a generally hexagonal framework with exterior panels 82A extending along the periphery or margin of the first circuit board and interior panels 82B traversing the intramarginal portion of the first circuit board in intersecting relation to form a plurality of pockets or cells 84. The stiffener couples movement of the boards in areas normally subjected to bending stresses thereby increasing the overall rigidity of the boards and decreasing the amount of deflection experienced by the boards in response to impact loads. The rigidity is further increased by orienting the panels perpendicular to the boards so that the bending section of the board assembly is effectively increased. Since the stiffener is made up of panels in an open framework, the increase in rigidity is not accompanied by a significant increase in the weight as compared to a package without a stiffener. As best seen in FIGS. 14-16, notches 86 are formed in rearward edges of some of the panels to provide vistas for electrical components mounted on the second circuit board so that the stiffener will lay flat against both boards to ensure proper coupling. The location of the cells 84 can also be arranged to contain electrical components. Since the notches and cells may not be symmetrical, the stiffener is preferably keyed to fit in the package only when properly oriented, for example by forming a rib 88 along the lower edge of the stiffener at a position which is laterally offset from the central longitudinal axis of the stiffener on a side of the stiffener opposite the rib 56 formed in the third recess of the housing compartment. In the event the stiffener is placed into the housing compartment in a reversed orientation, the rib on the stiffener will be on the same side as the rib in the third recess of the compartment. The ribs will abut one another thereby preventing the stiffener from being fully inserted into the compartment and alerting the installer of the mistake. Damage to the circuit components on the second board is thereby avoided. To ensure that the ribs abut one another when the stiffener is improperly installed, a pair of spaced ribs 90 are centered along the top of the stiffener to receive the upper post 80 therebetween so that the stiffener is aligned with the housing. The stiffener can be made of any material that is suitably rigid to couple deflections of the first and second circuit boards but is preferably made of nylon. The open framework design of the stiffener reduces weight while ensuring that bending forces affecting central or intramarginal portions of the boards are coupled.

Referring again to FIG. 2, a battery contact 92 in the form of a conductive band or ring is shown disposed within the battery compartment of housing 22 between the terminal contact 64 on front cover 24 and the second circuit board 16 to complete the circuit. The band or ring extends around battery 20 and contacts terminal contact 64 when the front cover is installed over the housing.

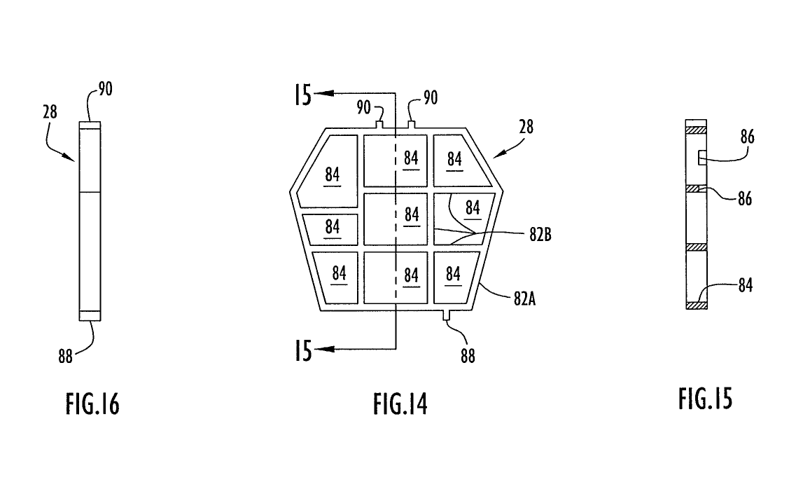

As mentioned above and shown in FIG. 2, rear cover 26 is generally triangular in shape with rounded corners and through-holes 94 formed at spaced locations about the periphery of the cover to receive screws that attach the rear cover to the housing. If desired, an optional pad (not shown) formed of a shock absorbing material such as a closed-cell foam can be disposed between the rear cover and the second circuit board to help cushion the board against impact forces. FIGS. 17-19 also show an optional exterior pad 30 which can be mounted on the back face of the rear cover 26 for applications where the sporting device is subject to extremely high impact forces caused by mounting the device directly in the path of application of the forces. The exterior pad is shown as a generally triangular pad having an opening 96 corresponding to the location of the radiating elements of the RF circuit and plural grooves formed in the pad around the openings to define ribs 100 which are spaced to allow lateral deformation of the ribs in response to impact loading. Opening 98 is for accommodating various markings in the part mold (e.g., web site, telephone number, etc.). The peak impact loads transmitted to the device are reduced as a result of the ribs deforming in this manner. To promote deformation of the ribs, the exterior pad is preferably formed of an elastomeric material such as Santoprene. The pad can be mounted on the rear cover using co-formation, adhesives, screws, hook and loop fasteners or any other fastening method.

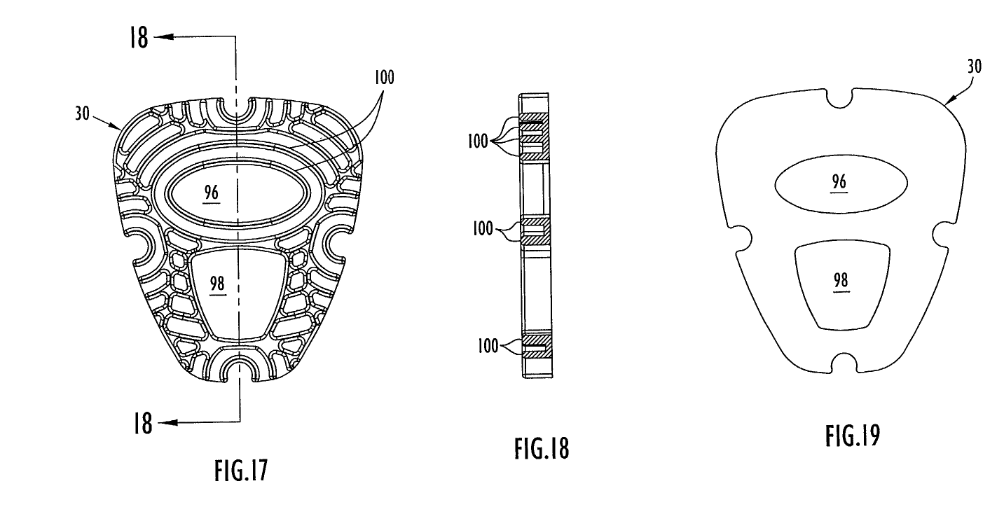

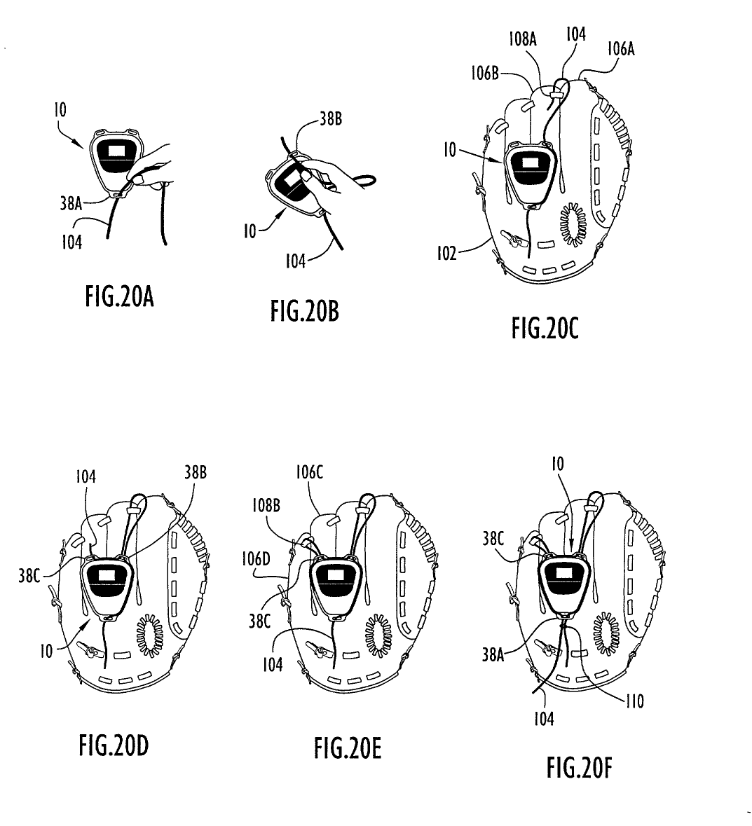

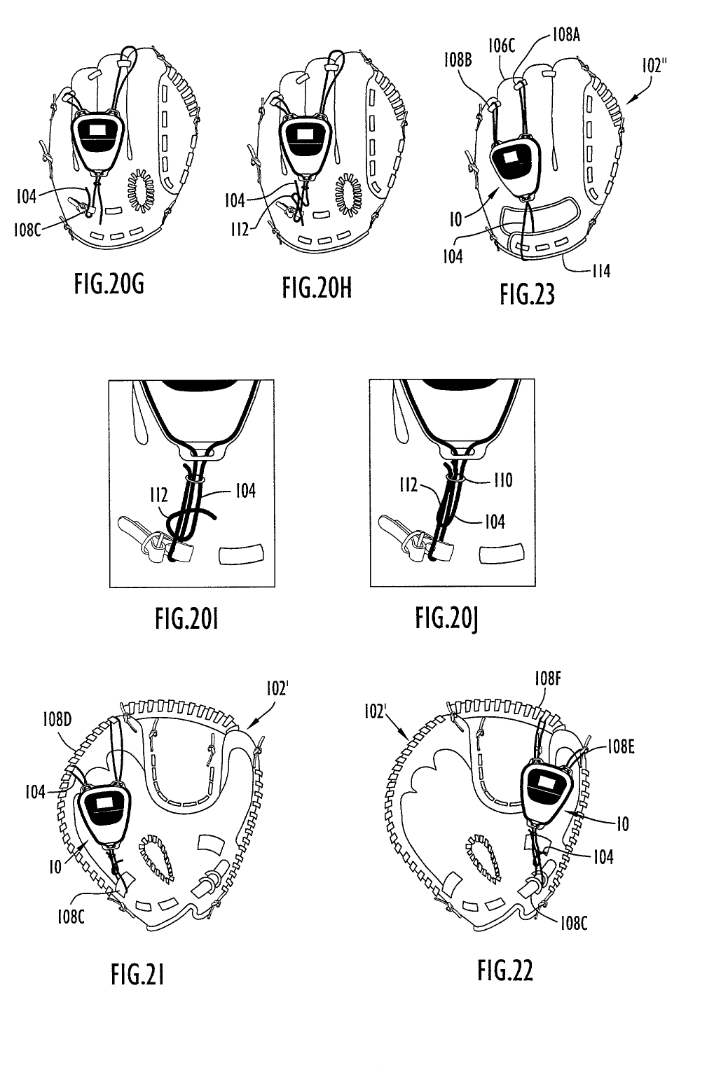

The packaging shown and described above allows a sports device such as a radar velocity sensor to be attached to sports equipment, clothing, or even parts of the body. As illustrated in FIGS. 20A-20J, a sports device 10 packaged in accordance with the present invention can be attached to the back of a ball catching glove 102 to measure the velocity of a ball thrown into the glove. Referring to FIG. 20A, a cord 104 is inserted through the eyelet 38A at the bottom of the device from front to rear and pulled about 3 to 4 inches from the eyelet. The other end of cord 104 is inserted through the upper right eyelet 38B of device 10, as shown in FIG. 20B, and is pulled while holding the lower end of the cord in place to take-up any slack so that the upper end of the cord is routed along the right side of the device as shown in FIG. 20C. With the upper end of cord 104 extending from the upper right eyelet, the back of the device is placed against the glove 102 behind the glove fingers about 1 to 3 inches below the finger tips as shown in FIG. 20C. The upper end of the cord is then pulled upwardly toward the glove finger tips and looped around the glove lacing 108A between the first and second fingers. Referring to FIG. 20D, the upper end of cord 104 is inserted through the upper right eyelet 38B again from back to front, routed across the top of device 10, and inserted through the upper left eyelet 38C from front to back. The upper end of the cord 104 is then pulled upwardly toward the glove finger tips, looped around the lacing 108B between the third and fourth glove fingers 106C and 106D, and pulled downwardly for insertion through the upper left eyelet 38C again from back to front as shown in FIG. 20E. The cord 104 is pulled through the upper left eyelet 38C and is routed along the left side of the device 10 for insertion through the lower eyelet 38A from front to back as shown in FIG. 20F. After taking-up the slack, a small elastic band or loop 110 is slipped over the ends of the cord and slid up toward the lower eyelet. The longer cord end is looped under and around a lower glove lace 108C, as shown in FIG. 20G, or any other glove feature around which the cord 104 can securely be looped. Ends of the cord 104 are then tied together in a tight knot 112, for example near the bottom of where the cord is attached to the glove as shown in FIGS. 20H and 20I, and free ends of the cord 104 placed within the elastic loop 110 as shown in FIG. 20J. Long, loose cord ends can be tucked between the device and the glove if desired.

If the glove does not have fingers, as in the case of a catcher's mitt or first baseman's glove 102′, the method of attaching the device 10 to the glove proceeds essentially as described above; however, the glove edge lacing 108D is used for the top two cord attachments, as shown in FIG. 21, by slipping the free end of the cord 104 under the lacing and looping the cord around the lace for a secure attachment of the device 10 to the glove.

A sports device 10 packaged according to the present invention can also be attached behind the thumb of a catchers mitt 102′ using a cord 104 as shown in FIG. 22 by looping the cord around the thumb edge lacing 108E for the first attachment, looping the cord around the web edge lacing 108F for the second attachment, and looping the cord around a lower lace 108C for the third attachment.

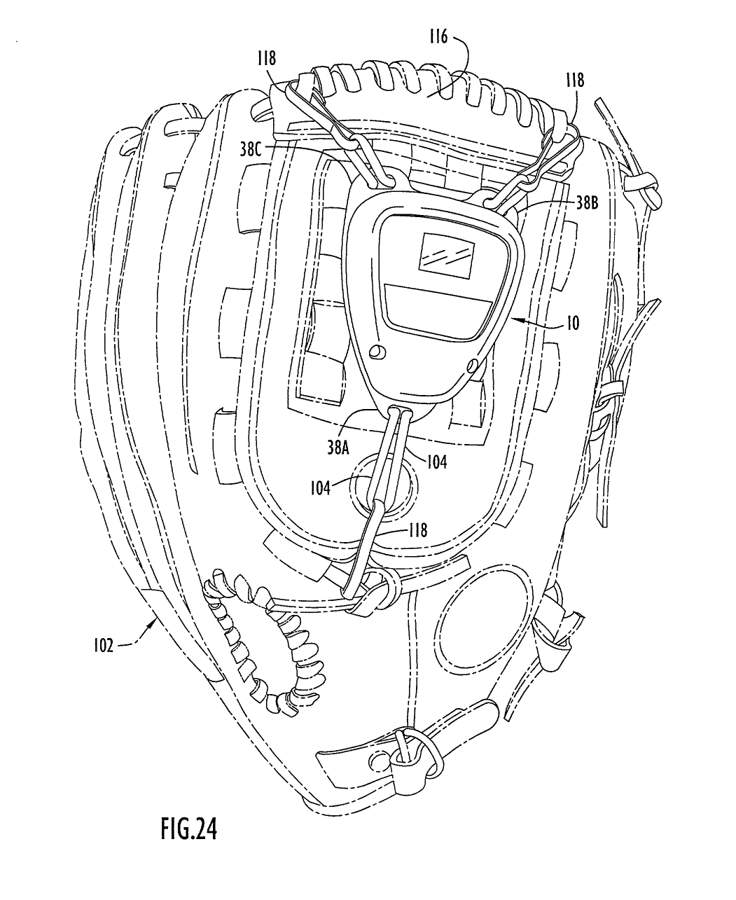

For small gloves 102″, attachment of a device 10 packaged according to the present invention proceeds essentially as described above; however, as illustrated in FIG. 23, the upper cord attachments are preferably made by looping the cord 104 around laces 108A and 108B on opposite sides of a glove finger (e.g., third finger 106C), and the lower cord attachment is made by looping the end of the cord around the wrist strap 114.

The use of a strong cord (e.g., parachute cord or other cords constructed of strong materials, such as nylon) and placement of the device on the back of the glove finger area ensures safe and reliable performance of the device even after encountering the severe impact forces created when catching a ball thrown at high velocities (i.e., greater than about 90 mph). For small gloves (i.e., less than 10 inch patterns), and for ball velocities less than 50 mph, the device may be attached behind the glove web. FIG. 24 illustrates a sports device 10 packaged according to the present invention and mounted behind the web 116 of a glove 102 using a continuous cord 104′ with ends doubled for insertion through the eyelets 38A, 38B and 38C and hooks 118 attached to the ends to attach to features of the glove. It will be appreciated, however, that a cord with free ends can be used in the manner described above to attach the device to the back of the web if desired.

From the above, it will be appreciated that the present invention makes it possible to package an otherwise fragile electronic sports device for attachment to sports equipment and other objects subjected to impact loading during use. In the case of an electronic sports device having plural circuit boards, the package includes a stiffener in the form of an open framework which is disposed between the circuit boards to couple the boards such that the effective sectional area of the board assembly is increased in the direction of bending without increasing the weight thereof significantly. The increased sectional area renders the board assembly stiffer than the individual boards such that deflection of each board is reduced. The stiffener is shown as a frame made up of plural panels oriented perpendicular to the board surfaces. It will be appreciated that the number and location of the panels can be varied to accommodate various types of circuits and that notches can be formed along any panel edge to create a vista for an electrical component on either board. When the stiffener is keyed, the key can take the form of a rib on top, bottom or sides of the stiffener. Alternatively, the stiffener can be keyed by virtue of being configured asymmetrically to fit within the compartment in one orientation only. While it is preferred that the stiffener include panels that extend around the periphery of a circuit board to facilitate alignment, the operational benefit of the stiffener can be achieved using a framework made up solely of panels that traverse the intramarginal portions of the board.

The package according to the present invention preferably includes eyelets which can be used to attach the sports device to objects such as ball catching gloves, for example by threading a cord through the eyelets and attaching portions of the cord extending through the eyelets to the glove lacing. The eyelets can be formed on the housing as shown or on any other part of the package including the front and rear covers. While three eyelets are shown, it will be appreciated that any number of eyelets can be used.

In the case of a sports device in the form of a radar velocity sensor, the package can be used to attach the device to objects such as gloves, heavy bags, punching mitts, racquets, golf clubs, baseball tees, vehicles, paintball guns, etc. With respect to the miniature radar device described above, the package can be used to attach the device to various supports, while the speed measuring device measures the speed of various types of moving objects. For example, the device may be mounted on a baseball glove or supported in some other fashion to measure the speed of a baseball or softball. Similarly, the device may be mounted on a hockey goalie or glove or supported in some other fashion to measure the speed of a hockey puck. Further, the device may be disposed within a baseball tee to measure the velocity of a bat swing. The device may be utilized to similarly measure the swing velocity in other sports, such as golf or tennis. Moreover, the device may be mounted on various martial arts type impact pads or bags to measure the velocity of strikes (e.g., punches, kicks, elbows, knees, etc.). The device may further be mounted on or in the proximity of a paint ball gun to measure the velocity of the paintballs. The device package may be modified in any fashion to accommodate a particular application and/or withstand impact forces of the moving object itself or those imparted to a receiving or other structure. It is to be understood that the device is not limited to the disclosed applications, but may be utilized to measure the speed of any moving object for sporting (e.g., baseball, softball, golf, tennis, hockey, lacrosse, football, etc.) or other purposes (e.g., measure speed of vehicles, runners, etc.).

The package shape and size can be varied dependent upon the type of sports device and the desired attachment method and location. While a generally triangular shape is shown, it will be appreciated that other shapes such as rectangular, elliptical, polygonal and asymmetrical shapes can be used. The locations of the display and the button can also be varied as desired. The package according to the present invention can also be used for electronic sports devices having no display and/or no button. Some examples of other types of electrical devices that can be packaged according to the present invention include force or acceleration sensors, range finders, stop watches or counters.

As described above, the packaging includes a battery compartment defined on the front face of the housing to receive a single cell battery. In a preferred embodiment, the compartment is cylindrical to hold a 3 Volt Lithium 1/3N cell such as those commonly denoted as CR-1/3N, DL-1/3N or 2L76BP cells; however, any number or type of cells can be used. Installation or replacement of the battery involves removing the screws attaching the front cover to the housing so that the battery compartment is accessible. After a battery has been placed in the compartment, the front cover can be reattached using the screws. In an alternate embodiment, a battery compartment can be formed on the back side of the housing so that a front cover is optional.

The lens can be configured with any combination of planar, concave or convex surfaces to achieve any desired degree of magnification of the display. An antiglare coating can be applied to the lens if desired.

When a cord with free ends is used to attach the packaging to another object, the free ends can be bound together using a knot, elastic band and/or any type of mechanical clip.

Inasmuch as the present invention is subject to many variations, modifications and changes in detail, it is intended that all subject matter discussed above or shown in the accompanying drawings be interpreted as illustrative only and not be taken in a limiting sense.

What is claimed is:

1. A package for a sporting device having a display and electrical components mounted on a pair of circuit boards comprising a housing defining a first chamber receiving the boards and the display;
front and back covers on opposite sides of the housing; and
a stiffener in the form of an open framework disposed between the boards.

2. A package for a sporting device as recited in claim 1 wherein said open framework is made up of a plurality of panels disposed perpendicular to respective opposing faces of the boards.

3. A package for a sporting device as recited in claim 2 wherein said panels extend around a marginal portion of at least one of the boards and traverse an intramarginal portion of the boards to form a plurality of cells.

4. A package for a sporting device as recited in claim 3 wherein a circuit component is mounted on at least one of the boards and at least one of said cells is arranged to contain the circuit component.

5. A package for a sporting device as recited in claim 4 wherein a notch is formed along an edge of a panel adjacent at least one of the boards to define a vista for a circuit component.

6. A package for a sporting device as recited in claim 5 wherein said stiffener is keyed to permit installation in one direction only so that said notch fits over the circuit component.

7. A package for a sporting device as recited in claim 6 wherein said key includes a rib formed on one side of said stiffener and a rib formed in said housing chamber on a side of said housing opposite said stiffener rib such that said ribs abut one another when said stiffener is installed improperly.

8. A package for a sporting device as recited in claim 1 and further comprising a shock-absorbing pad on a back face of the back cover.

9. A package for a sporting device as recited in claim 8 wherein said shock-absorbing pad includes a plurality of spaced ribs.

10. A package for a sporting device as recited in claim 9 wherein the spacing between said ribs is sufficient to permit lateral expansion of said ribs when compressed in response to an impact force.

11. A package for a sporting device as recited in claim 1 wherein said housing further includes a plurality of eyelets at spaced locations about the periphery of said housing.

12. A package for a sporting device as recited in claim 11 and further comprising a cord inserted through said eyelets to attach the device to another object.

13. A package for a sporting device as recited in claim 12 wherein said cord includes free ends looped through said eyelets and bound together.

14. A package for a sporting device as recited in claim 12 wherein said cord forms a continuous elastic loop with doubled portions inserted through said eyelets and further comprising hooks attached to said doubled portions to attach the device to another object.

15. A method of attaching a radar velocity sensor to a catching glove with glove lacing comprising the steps of threading a cord through a plurality of eyelets extending from a package containing the radar velocity sensor; and
attaching portions of the cord extending through the eyelets to the glove lacing.

16. A method as recited in claim 15, wherein the cord includes free ends and said threading and attaching steps include the steps of passing a free end through a first eyelet, looping the free end around the glove lacing at a first location, and passing the free end back through the first eyelet.

17. A method as recited in claim 16, wherein said passing and looping steps are repeated for a plurality of eyelets and locations on the glove lacing.

18. A method as recited in claim 17, and further comprising the step of binding the free ends together.

19. A method as recited in claim 18, wherein said binding step includes the step of tying the free ends around a lower glove lace.

20. A method as recited in claim 18, wherein the glove includes a wrist strap and said binding step includes the step of tying the free ends around the wrist strap.

21. A method as recited in claim 15, wherein the glove includes fingers and the sporting device is positioned behind the glove fingers.

22. A method as recited in claim 15, wherein the glove has edge lacing but no fingers and the sports device is attached to the glove edge lacing.

23. A method as recited in claim 15, wherein the glove has a web between the thumb and the finger portion of the glove and wherein the sports device is mounted behind the web.

24. A method as recited in claim 15, wherein the cord is continuous and said threading step includes forming the cord into a corresponding plurality of loops and inserting each loop through an eyelet.

25. A method as recited in claim 24, wherein a clip is secured to each loop and said attaching step includes engaging the glove lacing with the clips.
